(19) United States
(12) Patent Application Publication
(10) Pub. No.: US 2025/0364806 A1
(43) Pub. Date: Nov. 27, 2025

(54) FAULT MANAGED POWER MAINTENANCE MODES

(71) Applicant: Cisco Technology, Inc., San Jose, CA (US)

(72) Inventors: Joel Richard Goergen, Soulsbyville, CA (US); Matthew Stroud, Allen, TX (US); Jason Dewayne Potterf, Austin, TX (US); Chad M. Jones, Doylestown, OH (US); Andrew Kosta Thanos, III, Belmont, CA (US)

(21) Appl. No.: 18/672,528

(22) Filed: May 23, 2024

(51) Int. Cl. H02J 3/00; H02J 13/00

(52) U.S. Cl. CPC H02J 3/001; H02J 13/00004; H02J 13/00028

(57) ABSTRACT

Devices, systems, and methods to enable a user to control initiation and execution of a maintenance mode in a power distribution system that includes a power transmitter subsystem that transmits power over a cable to a power receiver subsystem. A maintenance mode associated with the power transmitter subsystem and the power receiver subsystem is initiated. The maintenance mode causes the power transmitter subsystem and power receiver subsystem to enter a power mode to allow for maintenance activity to be performed at the power transmitter subsystem and power receiver subsystem. An authorization server is configured to authorize initiation of the maintenance mode on the power transmitter subsystem and power receiver subsystem.

### TECHNICAL FIELD

The present disclosure relates to power delivery systems.

### BACKGROUND

Attending to maintenance issues at a physical site that receives fault managed power from a central office involves challenges to ensure that a technician can perform certain tasks while not degrading operations of the site. At the same time, the ability to detect a fault on a power line should be maintained so as to prevent harm to the technician.

### BRIEF DESCRIPTION OF THE DRAWINGS

FIG. 1A illustrates a block diagram of a power delivery system that is configured to enable and control initiation of a maintenance mode by a user from a user device, according to an example embodiment.

FIG. 1B is a block diagram of a user device of the system shown in FIG. 1A, according to an example embodiment.

FIG. 2A illustrates a block diagram of a power transmitter that may be used in the power delivery system, according to the techniques presented herein.

FIG. 2B illustrates a block diagram of a power receiver that may be used in the power delivery system, according to the techniques presented herein.

FIG. 2C illustrates a block diagram of a power transmitter and a power receiver, both of which may include a digital fuse arrangement for fault management, according to the techniques presented herein.

FIG. 3 is a block diagram of a power delivery system in which a power transmitter subsystem is part of a central office and a power receiver subsystem is part of each of a plurality of cell sites that communicate with the central office, according to an example embodiment.

FIG. 4 is a sequence diagram generally depicting operation of the power delivery system of FIG. 3, according to an example embodiment.

FIG. 5A is a block diagram that depicts an example of one scenario to authenticate a user device to initiate a maintenance mode in a power delivery system, according to an example embodiment.

FIG. 5B is a block diagram that depicts an example of another scenario to authenticate a user device to initiate a maintenance mode in a power delivery system, according to an example embodiment.

FIG. 6 is a flow chart depicting a method according to an example embodiment.

FIG. 7 is a block diagram of a system that enables control of maintenance mode initiation among a plurality of users, according to an example embodiment.

FIG. 8 is a diagram of a power delivery system and depicting an arrangement for managing multi-user access to maintenance mode activity, according to an example embodiment.

FIG. 9 is a flow chart depicting a decision process used to manage multiple users contending for maintenance mode control in a power delivery system, according to an example embodiment.

FIG. 10 is a block diagram of a device that may be configured to perform operations on behalf of any of the various entities forming a part of the power delivery system presented herein, according to an example embodiment.

### DETAILED DESCRIPTION

### Overview

According to an example embodiment, a system is provided comprising: a power transmitter subsystem configured to transmit power over one or more cables; a power receiver subsystem configured to receive the power over the one or more cables; a user interface and a control station. The user interface is configured to initiate a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem. An authorization server is configured to authorize initiation of the maintenance mode on the power transmitter subsystem and power receiver subsystem.

### Example Embodiments

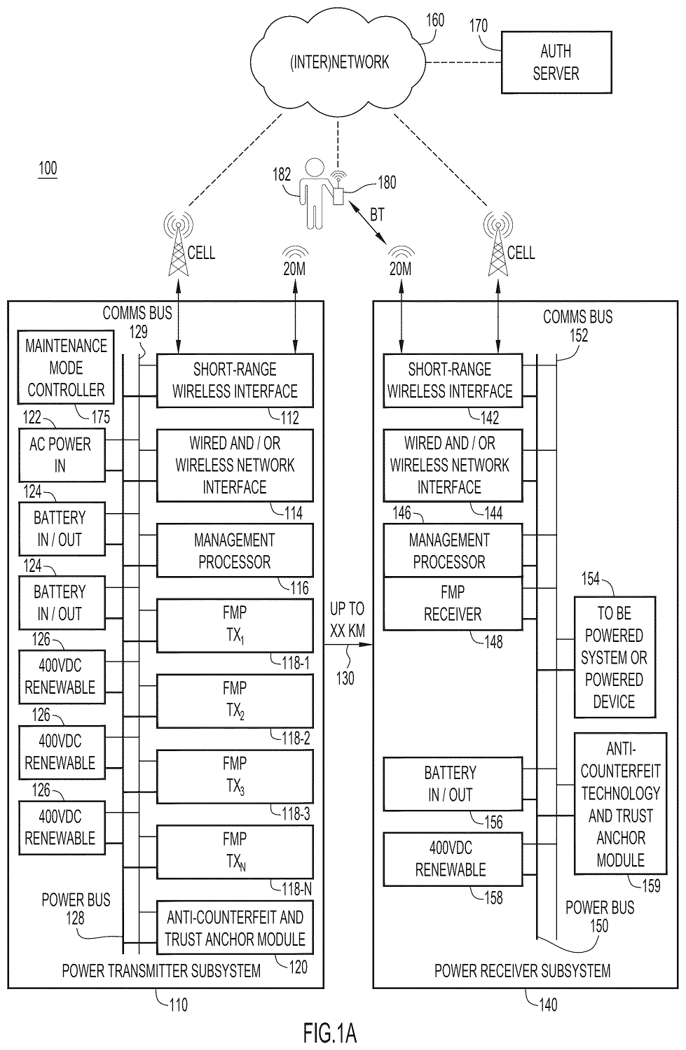

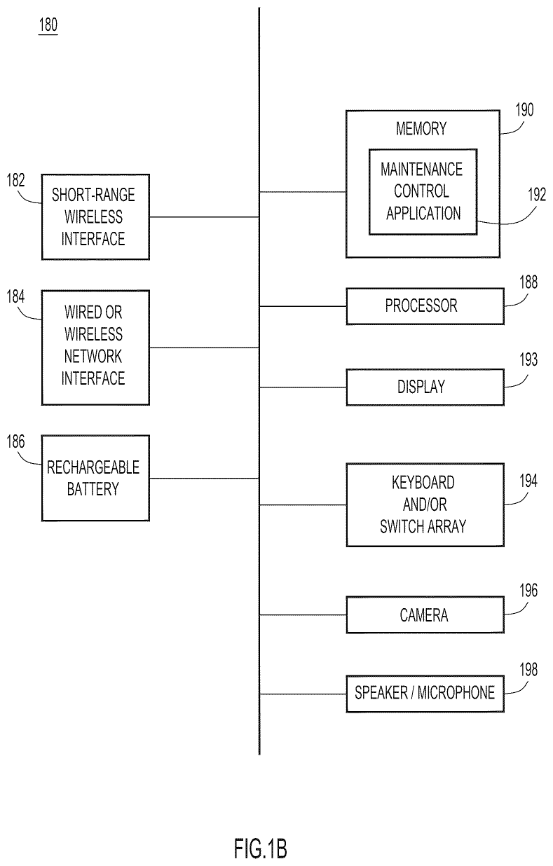

Presented herein are devices, systems, and methods to enable a user to control initiation and execution of a maintenance mode in a power distribution system that includes a power transmitter subsystem that transmits power over a cable to a power receiver subsystem (or to multiple power receiver subsystems). Reference is first made to FIG. 1A, which shows a block diagram of a power distribution system 100 that includes a power transmitter subsystem 110 that is coupled by one or more cables 130 to a power receiver subsystem 140. As will become apparent from the description below, there may be a plurality of power receiver subsystems 140 in a given system deployment. The system 100 may further employ a network 160 (e.g., the Internet), a authentication/authorization server (auth server) 170 and a hand-held user device 180 that a user (technician) 182 carries to initiate a maintenance mode in the power distribution system 100. The auth server 170 may be execute an authentication/authorization application service running that acts as a dashboard and control point for the operations of the power transmitter subsystem 110 and power receiver subsystem 140, and in particular for the authentication of a user and a user device to execute a maintenance mode, as described herein.

The power transmitter subsystem 110 includes a short-range wireless interface 112, a wired and/or wireless network interface 114, a management processor 116, and one or more fault managed power (FMP) transmitters 118-1, 118-2, 118-3, . . . 118-N. The short-range wireless interface 112 may be configured to operate in accordance with a wireless communication standard, such as the Bluetooth® short-range wireless communication standard. The wired and/or wireless network interface 114 may be configured to enable one or more wireless wide area network (WWAN) communications (e.g., cellular 4G, LTE, 5G, etc.), wireless local area network (WLAN) communications (e.g., Wi-Fi® wireless network communications) and a wired (Ethernet) network communications. To this end, the wired and/or wireless network interface 114 may be composed of multiple interface chipsets/cards for each communication type.

The management processor 116 may be a computer processor (or multiple computer processors) that execute instructions stored in associated memory to control the power transmitter subsystem 110. FMP transmitters 118-1 to 118-N are power transmitters that are capable of shutting down power when a fault is detected on a wire in the cable 130 that carries power to the power receiver subsystem 140. Each FMP transmitter 118-1-118-N may be configured to provide a different type of FMP power. The management processor 116 may be configured to control the operations of the power transmitter subsystem 110 to enter a maintenance mode, as described further below.

The term “Fault Managed Power (FMP)” as used herein may refer to power (e.g., >100 W), high voltage (e.g., >56V) delivered on one or more wires or wire pairs in such a way to allow for the power over the one or more wires or wire pairs to be terminated upon detecting a fault condition on the wire that could be harmful to a human, for example. In one implementation, power and data may be transmitted together (in-band) on at least one wire pair. FMP may involve fault detection (e.g., fault detection (safety testing) at an initialization stage, and thereafter on an ongoing basis during power delivery. The power may be, but is not required to be, pulse power comprising high power pulses separated by off times, and fault detection may be performed during the off times. The power may be transmitted with communications (e.g., bi-directional communications) or without communications.

The term “pulse power” (also referred to as “pulsed power”) refers to power that is delivered in a sequence of pulses (alternating low direct current voltage state and high direct current voltage state) in which the voltage varies between a very small voltage (e.g., close to 0V, 3V) during a pulse-off interval and a larger voltage (e.g., >12V, >24V) during a pulse-on interval. High voltage pulse power (e.g., >56 VDC, >60 VDC, >300 VDC, ^{˜}108 VDC, ^{˜}380 VDC) may be transmitted from power sourcing equipment to a powered device for use in powering the powered device. Pulse power transmission may be through cables, transmission lines, bus bars, backplanes, PCBs (Printed Circuit Boards), and power distribution systems, for example. It is to be understood that the power and voltage levels described herein are only examples and other levels may be used.

As noted above, safety testing (fault sensing) may be performed through a low voltage safety check between high voltage pulses in the pulse power system. Fault sensing may include, for example, line-to-line fault detection with low voltage sensing of the cable or components and line-to-ground fault detection with midpoint grounding. The time between high voltage pulses may be used, for example, for line-to-line resistance testing for faults and the pulse width may be proportional to DC (Direct Current) line-to-line voltage to provide touch-safe fault protection. The testing (fault detection, fault protection, fault sensing, touch-safe protection) may comprise auto-negotiation between power components. The high voltage DC pulse power may be used with a pulse-to-pulse decision for touch-safe line-to-line fault interrogation between pulses for personal safety.

In one or more embodiments, FMP may comprise pulse power transmitted in multiple phases in a multi-phase pulse power system with pulses offset from one another between wires or wire pairs to provide continuous power. One or more embodiments may, for example, use multi-phase pulse power to achieve less loss, with continuous uninterrupted power with overlapping phase pulses.

The power transmitter described herein may supply any of a variety of types of power, including 380 VDC, 380 VDC fault managed power (FMP), 48 VDC, 240 volts AC (VAC), 120 VAC, 480/277 VAC, Power over Ethernet (POE), 24 VAC control, and up to, and exceeding, 1000 VDC and 750 VAC. The 380 VDC FMP refers to pulse power delivered in a series of pulses of power spaced by off periods, and during the off periods fault detection techniques may be performed.

FMP may be converted into Power over Ethernet (POE) and used to power electrical components. In one or more embodiments, power may be supplied using Single Pair Ethernet (SPE) and may include data communications (e.g., 1-10GE (Gigabit Ethernet)). The power system may be configured for PoE (e.g., conventional PoE or PoE+ at a power level <100 watts (W), at a voltage level <57 volts (V), according to IEEE 802.3af, IEEE 802.3at, or IEEE 802.3bt), Power over Fiber (PoF), advanced power over data, FMP, or any other power over communications system in accordance with current or future standards, which may be used to pass electrical power along with data to allow a single cable to provide both data connectivity and electrical power to components (e.g., battery charging components, server data components, electric vehicle components). To be clear, FMP may involve pulse power or continuous non-interrupted power.

The power transmitter subsystem 110 may further include an anti-counterfeit and trust anchor module (TAM) 120 that is used to enable secure access to the power transmitter subsystem 110 by the user device 180.

The power transmitter subsystem 110 may further include an AC power input 122, one or more rechargeable batteries 124 (with input and output) and one or more renewable power sources 126 (e.g., 400 volts DC (VDC).

There is a power bus 128 that provides power to the various components of the power transmitter subsystem 110 and a communication bus 129 that enables data communications among the various components of the power transmitter subsystem 110.

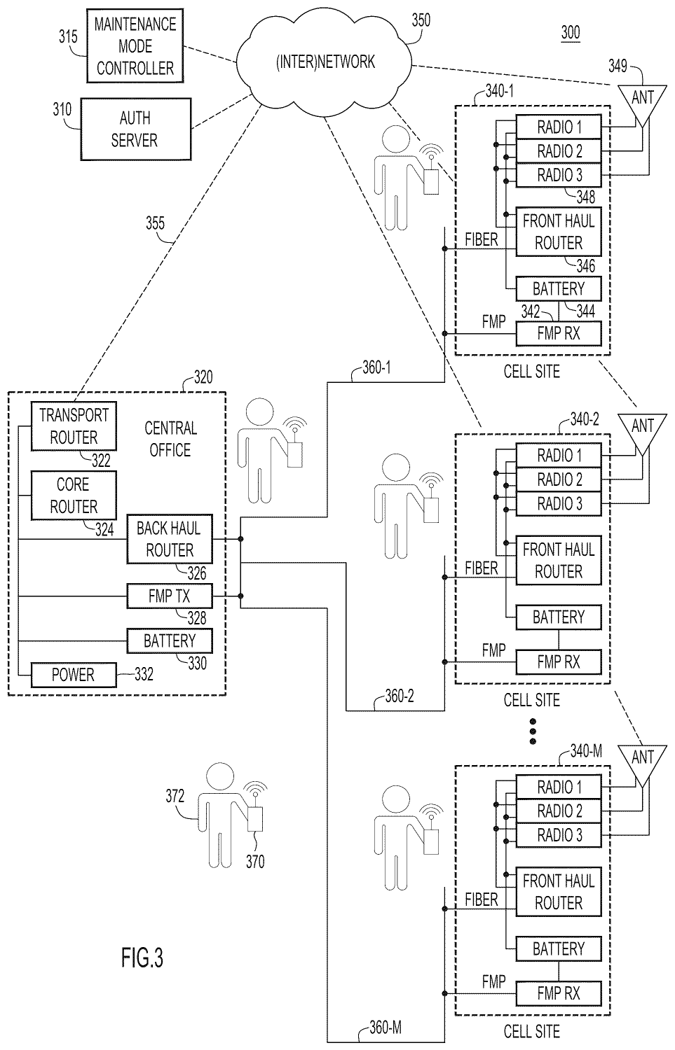

The power receiver subsystem 140 includes a short-range wireless interface 142 and a wired and/or wireless network interface 144 (similar to the short-range wireless interface 112 and the wired and/or wireless network interface 114, respectively, of the power transmitter subsystem 110). The power receiver subsystem 140 further includes a management processor 146 and an FMP receiver 148. The management processor 146 performs overall control functions for the power receiver subsystem 140, and like the management processor 116 of the power transmitter subsystem 110, may also control operations of the power receiver subsystem 140 when a maintenance mode is executed in the system 100. The FMP receiver 148 receives the power from one of the FMP transmitters 118-1 to 118-N of the power transmitter subsystem 110 and provides the power to the various other components of the power receiver subsystem 140. To this end, the power receiver subsystem 140 includes a power bus 150 that is configured to provide power to the various components and a communication bus 152 that is configured to enable data communications between the various components. There is a system to be powered (powered device) 154 in the power receiver subsystem 140, such as a networking device, wireless transceiver devices, etc., as described further below in connection with FIG. 3. The power receiver subsystem 140 also optionally includes a rechargeable battery 156 and a renewable power source 158 (e.g., 400 VDC). Like the power transmitter subsystem 110, the power receiver subsystem 140 may include an anti-counterfeit and trust anchor module 159.

The power transmitter subsystem 110 and power receiver subsystem 140 (also referred to here as “equipment”) are configured to verify a “change of maintenance mode” request and to perform the requested mode changes. Maintenance mode definitions can vary depending on certain power delivery applications, but each mode may create various timing/safety conditions that are analyzed to determine a hazard level that mode creates for a maintenance worker. The equipment may employ a communication method for an “agent” to convey a request. For example, the request may be a physical request, meaning a request that is made by a hard-wired control button, switch or relay or other direct user interface mechanism. The request may also be a “virtual” request, such a request made via a remote network or cloud access, via a local wireless connection (wireless local area network, short-range wireless, etc.) or via a local wired network (Ethernet, Universal Asynchronous Receiver/Transmitter (UART), Universal Serial Bus (USB), etc.)

One or more “agents” may request to change the maintenance mode of equipment. Agents can be maintenance workers, administrators, or even automated software components. Agents can perform two main classes/types of requests: a secure physical request and a secure virtual request. A secure physical request are implicitly authorized by virtue of the controls being in a secure physical environment/area (guaranteed by physical access controls). Again, example interfaces are a local button or switch or a local physical LOTO mechanism (described further below). A secure virtual request needs to be authorized by a virtual authority, using, for example, standard techniques (e.g., key pair public/private key cryptographic systems (PKCS)). Example interfaces for a secure virtual request may include a mobile application/device, control software running on a network operations center or elsewhere in the cloud, a badge reader, a keypad/keyboard or other virtualized LOTO console.

The auth server 170 runs an authentication/authorization service for secure virtual requests. The auth server 170 can reside in the cloud, in a network operations center (NOC), or in the equipment. The auth server 170 authenticates the identity of requesting agents, as certifies that a requesting agent has the authority to perform the requested maintenance mode change. In one example, the auth server 170 cryptographically signs and issues maintenance authorization certificates for requests so that they can be independently validated by other system entities.

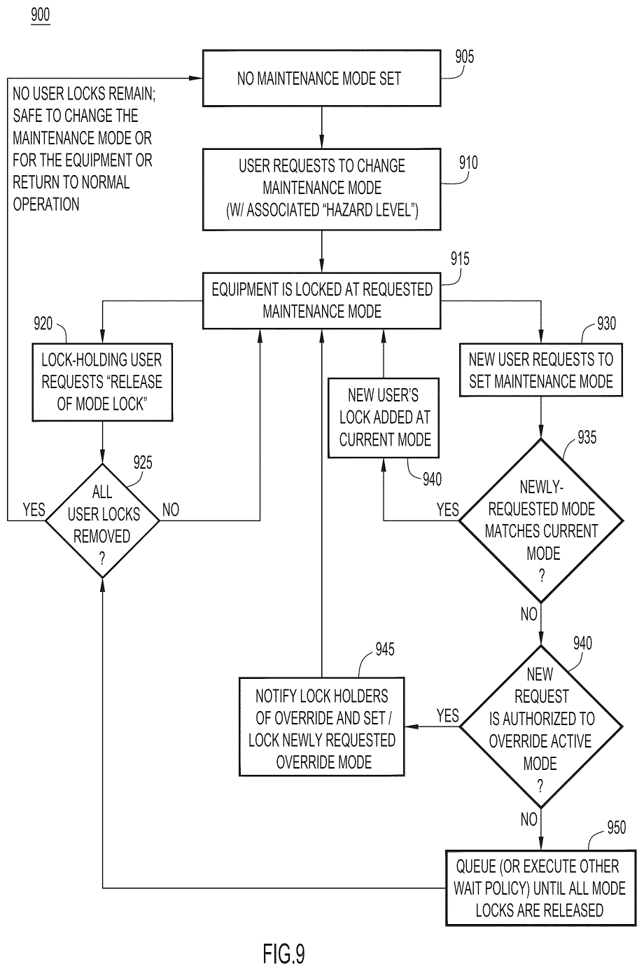

FIG. 1A further shows a maintenance mode controller 175 that is part of the power transmitter subsystem 110, according to an example embodiment. The maintenance mode controller 175 may be a separate (microprocessor-driven) controller that runs one or more software programs to perform a multi-user lock-out tag-out (LOTO) features, as described further below. The maintenance mode controller 175 accepts and validates one or more authorized maintenance mode change requests from users, and is configured to look up or otherwise determine a requested maintenance mode. The maintenance mode controller 175 also resolves conflicts between multiple maintenance mode requests from multiple valid mode change requests according to the state diagram of FIG. 9. This includes resolving maintenance mode request conflicts between virtual and physical mode change requests (if applicable). Furthermore, the maintenance mode controller 175 directs affected equipment to change maintenance mode according to the output of the maintenance mode request arbitration process of FIG. 9.

While FIG. 1A shows that the maintenance mode controller 175 is part of the power transmitter subsystem 110, it can reside entirely in the cloud or its functions can be distributed across equipment and the cloud. Communication with the maintenance mode controller 175 can be via local direct communication or secure remote communication with equipment (if the maintenance mode controller 175 is not co-located on equipment, e.g., the power transmitter subsystem 110 or power receiver subsystem 140).

For embodiments where physical maintenance requests can be made, one function of the maintenance mode controller 175 is to resolve conflicts between multiple physical and virtual requests. If the equipment cannot communicate with a fully-remote maintenance state controller then this conflict is resolved locally. In such embodiments, secure physical requests may be treated as implicitly authorized overrides and the resolution performed on the equipment. These aspects are described below.

A user (technician/maintenance worker/administrator) 182 carries the user device 180 hand-held user device to select and initiate a selected maintenance mode (of a plurality of available maintenance modes) in the power distribution system 100. The user device 180 can take on a variety of forms such as a smartphone or tablet computer running a maintenance control application, or a specialized hand-held compute device. To this end, reference is now made to FIG. 1B, which shows a block diagram of user device 180 shown in FIG. 1A and described herein. The user device 180 includes a short-range wireless interface 182, a wired and/or wireless network interface 184, a rechargeable battery 186, a processor 188, memory 190 that stores instructions for a maintenance control application 192, a display 193, a keyboard 194 (and/or array of switches that may be used to initiate commands (e.g., maintenance mode selection commands, etc.), camera 196 and speaker/microphone 198. The camera 196 and speaker/microphone 198 may be optional components; they are not needed for communication or initiating a maintenance session, but can be useful in the even recording of audio and/or video for a maintenance session is desired. The user device 180 may communicate with a power transmitter subsystem and a power receiver subsystem using the short-range wireless interface 182 or the wired and/or wireless network interface 184. The wired and/or wireless network interface 184 may be used to enable communication between the user device and the auth server 170 shown in FIG. 1A, for example.

In one form, the processor 188 executes instructions for the maintenance control application 192 stored in memory 190 to perform various operations for the user device, as described herein. The display 193 may have touch-screen display capabilities to enable a user to interact with the maintenance control application 192, in which case the keyboard 194 may not be necessary. In any case, a user may interact with the user device 180 via the display 193, keyboard 194 as well as the speaker/microphone 198. The camera 196 may be used to capture still photographs or video, such as around equipment in the power distribution system, as well as to capture image data of a user for use in authenticating the user to perform maintenance operations.

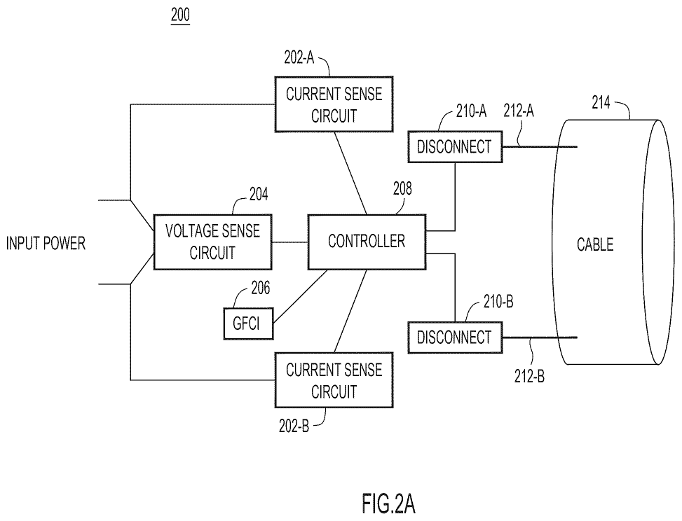

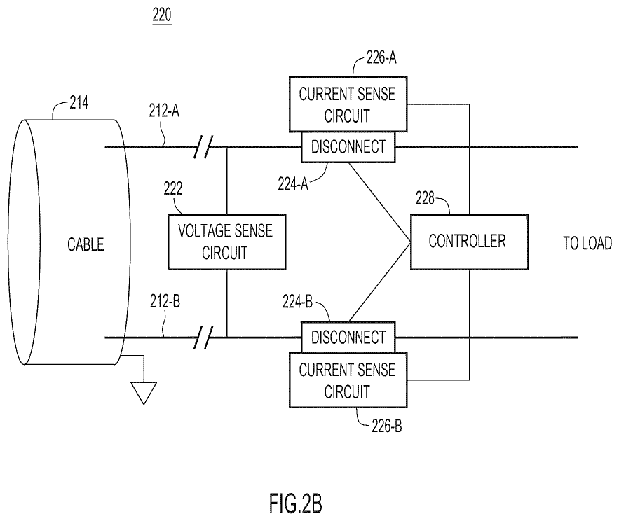

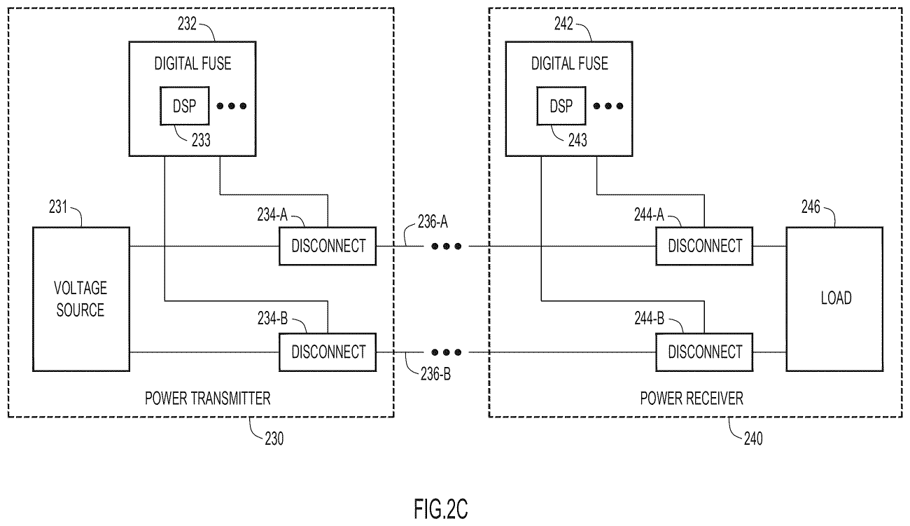

The FMP transmitters and 118-1 to 118-N and the FMP receiver 148 may take various forms to achieve the fault managed power operation useful to interrupt power for safety applications. FIGS. 2A, 2B and 2C illustrate non-limiting examples of power transmitters and power receivers that may be used as FMP transmitters and FMP receivers in the embodiments presented herein.

FIG. 2A illustrates a block diagram of a power transmitter 200 (which may be referred to as a power sourcing equipment) configured to perform and participate in the maintenance mode techniques presented herein. The block diagram of the power transmitter 200 shown in FIG. 2A may be suitable for the FMP transmitters 118-1 to 118-N shown in FIG. 1A. The power transmitter 200 may include two current sense circuits (current sensors) 202-A and 202-B, a voltage sense circuit (voltage sensor) 204, a ground fault circuit interrupter (GFCI) 206, a controller 208 and two disconnects 210-A and 210-B. The GFCI 206 can operate any time (even when power is being delivered onto lines 212-A and 212-B) because it looks for mismatches as to what current is sent on one line and what current comes back on the other line.

The current sense circuits 202-A and 202-B are associated with respective lines of a loop and are coupled to the disconnects 210-A and 210-B, respectively, which are in turn connected to lines 212-A and 212-B that may be contained within a cable 214.

Power is input onto two current paths. Each of these current paths traverses a current sensor, e.g., current sense circuit 202-A and 202-B, and their relative voltage is measured by the voltage sense circuit 204. The controller 208 receives the measurements from the current sense circuits 202-A and 202-B and the voltage sense circuit 204. The controller 208 may also be responsive to the GFCI 206 during power delivery time periods for added safety. The current sense circuits 202-A and 202-B measure current and passes these values to the controller 208. The current then flows to disconnect 210-A onto line 212-A into the cable 214 (to the power receiver) and comes back on the return current path on line 212-B into disconnect 210-B.

The controller 208 actuates at least one of the disconnects 210-A and 210-B to isolate power source current from the lines 212-A and 212-B (forming a current loop when connected at opposite ends to a power receiver) in the event safety criteria is not met according to the evaluation by the controller 208 of the line conditions (line-to-line fault detection, a line-to-ground fault as detected by the GFCI 206, or other current or voltage conditions detected by the controller 208). The disconnects 210-A and 210-B may be relays or switches, such as field effect transistor (FET) switches, and in some embodiments, back-to-back FETs. The controller 208 may be a microprocessor, microcontroller, or other digital logic device (with fixed or programmable digital logic gates) configured to perform the techniques described herein.

FIG. 2B is a block diagram of a power receiver 220 that is coupled to a cable, e.g., cable 214, containing lines 212-A and 212-B from the power transmitter shown in FIG. 2A, as an example. The power receiver 220 includes a voltage sense circuit 222, disconnects 224-A and 224-B that are connected to lines 212-A and 212-B, respectively, current sense circuits 226-A and 226-B connected to sense current on lines 212-A and 212-B, respectively, and a controller 228. As explained above, the lines 212-A and 212-B form a current loop between a power transmitter and the power receiver 220.

The power receiver 220 receives power on lines 212-A and 212-B of the cable 214 as input, with an optional ground reference. The voltage sense circuit 222 makes a voltage measurement on the incoming power for telemetry, loop resistance calculation, or any other reason associated with the techniques presented herein. This current path then traverses disconnects 224-A and 224-B as well as current sense circuits 226-A and 226-B on the respective line to enforce current limits. The disconnects 224-A and 224-B may be FETs, relays, etc.

The controller 228 may be a microprocessor, microcontroller, or other digital logic device (with fixed or programmable digital logic gates) configured to perform the fault detection and alerting techniques described herein. The controller 228 may be configured to modulate at least one of the disconnects 224-A and 224-B by disconnecting the further power reception stages at the required interval to force a known current draw (likely near zero or some higher level of current to avoid edge of detection range sensitivity issues). This demonstrates to the power transmitter that no faults are present on the lines 212-A and 212-B and the power receiver is up and running. An optional load equipment ground conductor may be provided if grounding of the load is required/desirable.

Again, one task of the controller 228 is to drive the at least one of disconnects 224-A and 224-B to disconnect from at least one of the lines 212-A and 212-B, respectively, to demonstrate safety at the required interval. The current sense circuits 226-A and 226-B may be employed to provide telemetry, and also to provide current measurement to the controller 228 if the load pulls too much current because of a short-circuit, etc.

FIG. 2C shows a power delivery system that includes a power transmitter 230 and a power receiver 240 according to still another fault managed power variation. The power transmitter 230 includes a voltage source (AC or DC) 231 and a digital fuse 232 that controls disconnects 234-A and 234-B coupled to the send wire 236-A and receive wire 236-B, respectively. The digital fuse 232 may include one (or more) digital signal processors (DSP) s 233. Similarly, the power receiver 240 includes a digital fuse 242 that controls disconnects 244-A and 244-B also coupled to the send wire 236-A and return wire 236-B, respectively, and provides received power to a load 246 (after isolation and other possible intervening circuits, if required). The digital fuse 242 includes one (or more) DSPs 243. At a high-level, the digital fuses 232 and 242 inject pulses (called “chirp pulses”) onto the wires 236-A and 236-B and analyze signals on the wires to detect whether there is an impedance-based fault on either the send wire 236-A or receive wire 236-B. The digital fuse may be used for situations where power is continuously applied over a wire as well as to situations in which power is provided in pulses separated by off intervals that can be used to perform fault detections.

In all of the variations of power transmitters and power receivers with fault management capabilities shown in FIGS. 2A, 2B, and 2C, it is to be understood that the controllers or DSPs of these entities may be respond to commands from the user device 180 and/or the auth server 170 to enter the appropriate power shut-off, fault detection, no fault detection, etc., operations for the various maintenance modes described below.

Reference is now made to FIG. 3, which shows an example instantiation of a system 300 that employs the concepts depicted in FIG. 1A for a wireless wide area network communication (cellular) system. The system 300 includes an auth server 310 (similar to the one shown in FIG. 1A), a maintenance mode controller 315, a central office 320 and a plurality of cell sites/base stations 340-1, 340-2, . . . 340-M. All of these entities are in communication with each other via a network 350 (e.g., the Internet). In this example instantiation, the maintenance mode controller 315 resides in the cloud. A relatively large network “pipe” 355 connects the central office 320 to the network 350. The central office 320 is connected to each of the plurality of cell sites/base stations 340-1 to 340-M via a respective cable 360-1, 360-2, . . . 360-M. Each cable 360-1 to 360-M may include copper wires (one or more wire pairs) to carry power as well as fibers to carry data between the central office 320 and the plurality of cell sites/base stations 340-1 to 340-M. The cables 360-1 to 360-M could be of various lengths (e.g., 2-10 or more kilometers), as an example. A given cable of the plurality of cables 360-1 to 360-M may carry multiple phases of power and multiple fibers for many data rates of data. FIG. 3 further shows a user device 370 and an associated user 372 that may perform maintenance in the system 300 at the central office 320 or any at any of the cables 360-1 to 360-M.

The central office 320 may include a transport router 322 to enable communication with the network 350, a core router 324, a back haul router 326 to enable communication with the cell sites 340-1 to 340-M, a power transmitter 328, a power source 330 and a battery 332. The power transmitter (FMP TX) 328 transmits power via cables 360-1 to 360-M to the cell sites 340-1 to 340-M, respectively.

Each cell site 340-1 to 340-M includes a power receiver (FMP RX) 342, a rechargeable battery 344, a front haul router 346, a radio block 348 comprising multiple radio transceivers (e.g., three radios) and antenna 349. In one example, the radio block 348 comprises multiple radio transceivers because there is one transceiver for each 120 degree portion of the antenna 349. The FMP power that each cell site receives from the central office 320 may be used to power the front haul router 346 and the radio transceivers of the radio block 348. The cell sites 340-1 to 340-M may have a small cabinet form factor.

When maintenance work is needed at a cell site, the central office, or on a cable carrying power (and data), that maintenance work could impact other functions at that location. Moreover, humans make mistakes, and such mistakes could cause injury as well as unintentionally impact functions in the system. Further still, there could be “bad actors” seeking to access or sabotage a central office or cell site. Accordingly, a mechanism would be useful to authenticate access to the infrastructure of a system, like the system 300 shown in FIG. 3, in order to perform various maintenance tasks at the central office, cell site or a cable.

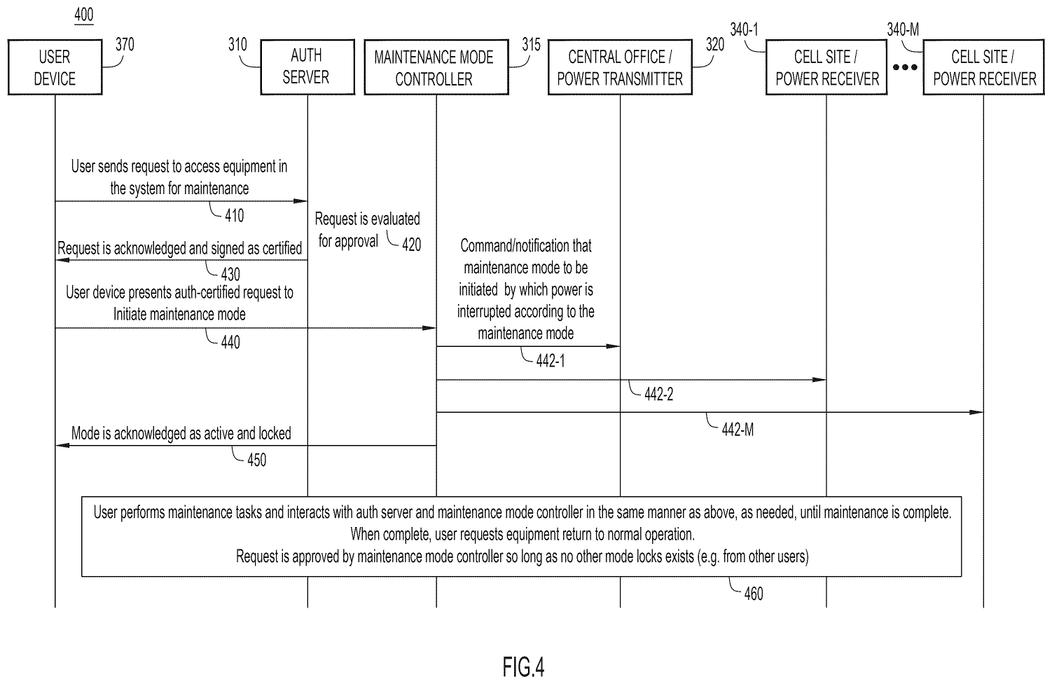

Reference is now made to FIG. 4, with continued reference to FIGS. 1A and 3. FIG. 4 shows a sequence diagram 400 depicting, at a high-level, an example of the interactions between the various entities to enable a user with a user device to initiate a maintenance mode to perform one or more maintenance tasks. To facilitate the description of FIG. 4, the interactions are described with respect to user device 370, auth server 310, maintenance mode controller 315, central office 320 (that includes a power transmitter, FMP TX 328), and cell sites 340-1 to 340-M. At step 410, a user sends a request, via the user device 370, to access equipment in the system (e.g., power transmitter in the central office or power receiver in a cell site) for a maintenance task. The request is directed to the auth server 310 through the cloud. At step 420, the auth server 310 evaluates the request to determine whether or not to approve it. Additional details are provided below for authenticating a user device and determining whether to approve a request. For the sake of this description, it is assumed that the auth server 310 approves the request, and at step 430, sends an acknowledgement to the user device 370.

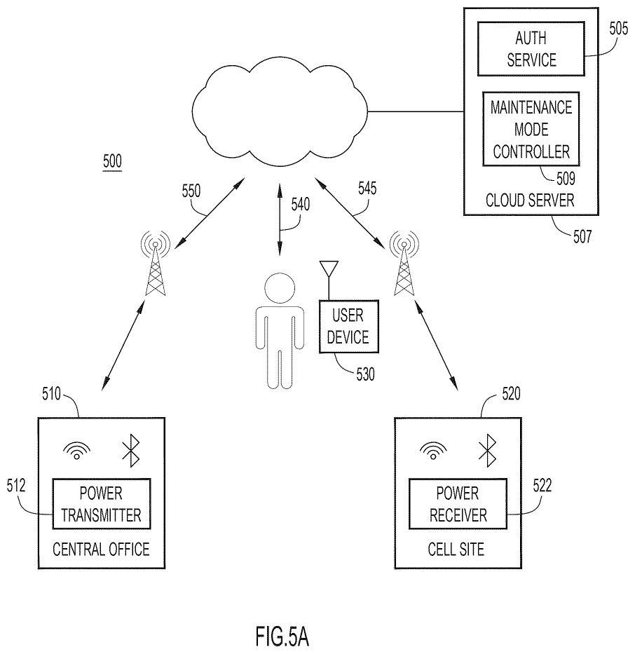

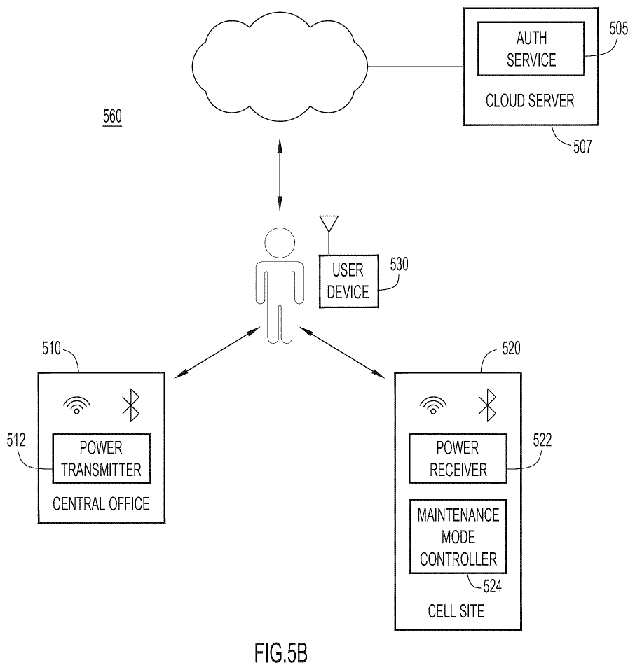

Next, at step 440, the user device presents an auth-certified request (request that is validated by the auth server 310) to the maintenance mode controller 315. The maintenance mode controller 315 sends a command/notification to the central office 320, at step 442-1, and to one or more particular cell sites (e.g., cell site 340-1), at steps 442-2 to 442-M. The notification indicates to these entities that a maintenance mode is about to be initiated by which power is interrupted according to the particular maintenance mode identified in the request. As explained below in connection with FIG. 5A, the notification may be configured with an authorization ticket that puts the central office 320 or a particular cell site (e.g., cell site 340-1) into a particular maintenance mode. The maintenance mode controller 315, at step 450, sends to the user device 370 an indication that the maintenance mode is acknowledged as active and locked.

At step 460, the user performs maintenance tasks and interacts with auth server 310 and maintenance mode controller 315 in the same manner as above, as needed, until maintenance is complete. When the maintenance tasks are complete, the user requests that the equipment return to normal operation. The maintenance mode controller 315 will approve a request as long as no other maintenance mode locks that exist (e.g., from other agents).

As explained above, implementation of the auth server 310 can vary. Embodiments with physical methods for enabling maintenance modes can be considered “implicitly authorized” by virtue of user's physical access to restricted areas, such as a badge reader in combination with a kiosk (screen, keypad or keyboard) or a physical button/lock/LOTO station.

Similarly, implementation of the maintenance mode controller 315 can vary. The maintenance mode controller 315 manages the maintenance mode of one or more power transmitter or power receiver units in a power distribution system to resolve maintenance mode conflicts and manage lock-out tag-out in multi-user maintenance environments. Again, the maintenance mode controller 315 can be integrated into the power transmitter or power receiver, or implemented as a cloud server or remote service reachable by user devices and power transmitters and power receivers.

Examples of various possible maintenance modes are described below.

The interactions between a user device and a power transmitter (e.g., at a central office) or a power receive (e.g., at a cell site) may be privileged, such that users and user devices are authenticated before they are given access to a maintenance mode of such equipment. Authentication of users setting a power transmitter or a power receiver in a maintenance mode and setting each state may be managed with a combination of techniques.

First, cloud-managed access control lists on a per user basis may be employed. For example, a power-down with no time limit maintenance mode (described in further detail below) may be permitted for only a subset of users who have maintenance mode privileges.

Second, device identity authentication may be used. This may be based on the source of the request such that it is controlled in the target deployment environment. Trusted devices may be preferred for direct communication with a power transmitter or power receiver. A trusted device is a device with a trusted anchor module (as shown in FIG. 1A) or other similar component or method to enable trusted access to the host device (e.g., power transmitter subsystem or power receiver subsystem). In addition, the target of the request may be managed through an authorization ticket that is issued to a user device for use with a particular target (a particular power transmitter or particular power receiver) such that authentication of the authorization ticket will succeed only for that target subsystem (the power transmitter or a particular power receive).

There may be mode setting scenarios that may be managed through the cloud or over a direct interface between a user device and a power transmitter or power receiver. For the cloud scenario, authentication, authorization, and auditability is centrally managed. When achieved through direct access (via short-range wireless, wireless local area network, or wired), then authorization may be first obtained from the cloud.

Reference is now made to FIG. 5A that illustrates an operational flow 500 for one scenario in which all the relevant entities have connectivity to the cloud, e.g., auth service 505 running in a cloud server 507, a maintenance mode controller 509 running in the cloud server 507, a central office 510 having a power transmitter 512, a cell site 520 having a power receiver 522, and a user device 530. At 540, at the initiation of a user, the user device 530 sends a request to the auth service 505 to set a power transmitter or power receiver (or both) into a maintenance mode. The auth service 505 verifies the request, generates an authorization ticket for a particular maintenance mode identified in the request and generated by the maintenance mode controller 509, and at 545 transmits the authorization ticket to the central office 510 or at 550 to the cell site 520. The central office 510 or cell site 520 authenticates the authorization ticket received from the auth service 505, and once authenticated, the central office 510 or cell site 520 is set to the maintenance mode level, according to what was indicated in the authorization ticket. Thereafter, the user device 530 can communicate with the central office 510 and/or cell site 520 to activate the maintenance mode.

Turning now to FIG. 5B, an operational flow 560 is now described for another scenario. FIG. 5B shows the same relevant entities as shown in FIG. 5A, e.g., an auth service 505 running in a cloud server, a central office 510 having a power transmitter 512, a cell site 520 having a power receiver 522, and a user device 530. Also, there is a maintenance mode controller 524 running in the cell site 520. This is useful if the cell site 520 does not have reliable remote connectivity to the cloud. In this scenario, the user device 530 has a direct connection to the central office 510 and cell site 520, and the user device uses local connectivity to provide an auth-certified request directly to the maintenance mode controller 524 in the relevant equipment, e.g., cell site 520. The auth service 505 is provisioned with an authorization key pair. The central office 510 and the cell sites 520 store authorization certificates in a trusted store, such as in the trust anchor modules (shown in FIG. 1A). The user device 530 has a direct connection to the central office 510 and cell site 520 via wireless or wired interface (e.g., Bluetooth, Wi-Fi, or Ethernet) as described above.

### Maintenance Mode Levels/Operations

As explained above, there may be several maintenance mode types or levels that a user may choose. The types of operational changes and the manner in which power is interrupted from the power transmitter over a cable to the power receiver may be different based on the maintenance model type or level.

### 1—Low Voltage/PoE Operation

This mode puts the system in Power-over-Ethernet (POE) or other low voltage operation at a power level that is safe to touch by a human. The copper wires connecting the power transmitter to the power receiver are powered with a low voltage, e.g., 60 V DC at 90 watts, similar to that of a PoE configuration. The equipment at the power receiver end of the system has limited power and limited communications capability. For example, there may be basic light emitting diode (LED) and test functionality at the power receiver end, and the wires carrying power are safe to touch due to the low voltage.

2—FMP No-Fault Mode with Time Limit

In this mode, power is continued to be delivered but without fault detection for a specified limited period of time. This mode could be hazardous but it may be useful in some debug cases. Once the control station/NOC grants the request for this maintenance mode, the control station/NOC will drive the central office/power transmitter and cell site to a “critical alarm” state. The power transmitter and power receiver will disable fault detection for the specified limited period of time. Once that timer expires, the power transmitter will stop transmitting power to the power receiver subsystem.

3—Return to FMP Mode with No Reset

This mode may be entered in response to a user request (while in another maintenance mode or upon completing a maintenance mode). The currently active maintenance mode is disabled and the power transmitter and power receiver are returned to the exact point (state) when the maintenance mode was initiated. In other words, this is not a complete reset so that state is saved at the power transmitter and power receiver to understand the last known working state. This mode may be useful for service providers and may be subject to approval by the control station/NOC. Service providers sometimes do not desire a full reset for the concern that someone may have made a programming change that was not saved, thereby increasing down time of that piece of equipment because it powers up in a different state than intended/desired. The states of the counters and registers in the control hardware at the power transmitter and power receiver are all kept as they were when the maintenance mode was requested.

### 4—Restart Normal

This mode is a normal restart after completing a maintenance mode, and involves a complete restart in which states of the power transmitter and the power receiver(s) are not maintained. All counters and registers in the control hardware at the power transmitter and power receiver are reset.

5—Forced Power-Down with No Time Limit

In this mode, power transmitted by the power transmitter is completely stopped/shut down. Service will be interrupted at the physical site of the power receiver. The maintenance person needs to send a request to the control station/NOC for power to be turned back on. The control station/NOC needs to approve the request, and once approved, restart begins per mode 4 above.

6—Forced Power-Down with Time Limit

In this mode, a time period is set for the power transmitter to stop all power on the wires in a cable. A counter or timer is set, and when the timer expires, restart begins per mode 4.

Other maintenance and power shut-down/control operations are envisioned, and the maintenance modes described above are examples, and not meant to be limiting.

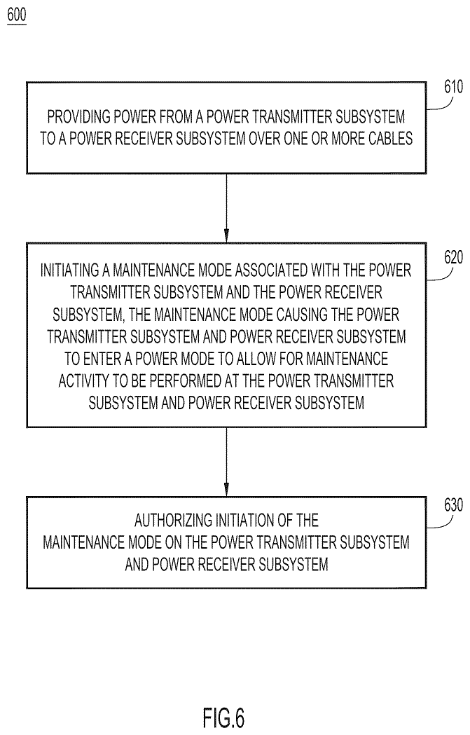

Turning now to FIG. 6, a flow chart is shown generally depicting operations of a method 600 according to embodiments presented herein. The method 600 includes, at step 610, providing power from a power transmitter subsystem to a power receiver subsystem over one or more cables. At step 620, the method includes initiating a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem. At step 630, the method includes, authorizing initiation of the maintenance mode on the power transmitter subsystem and power receiver subsystem.

### Multi-User Lock-out Tag-out

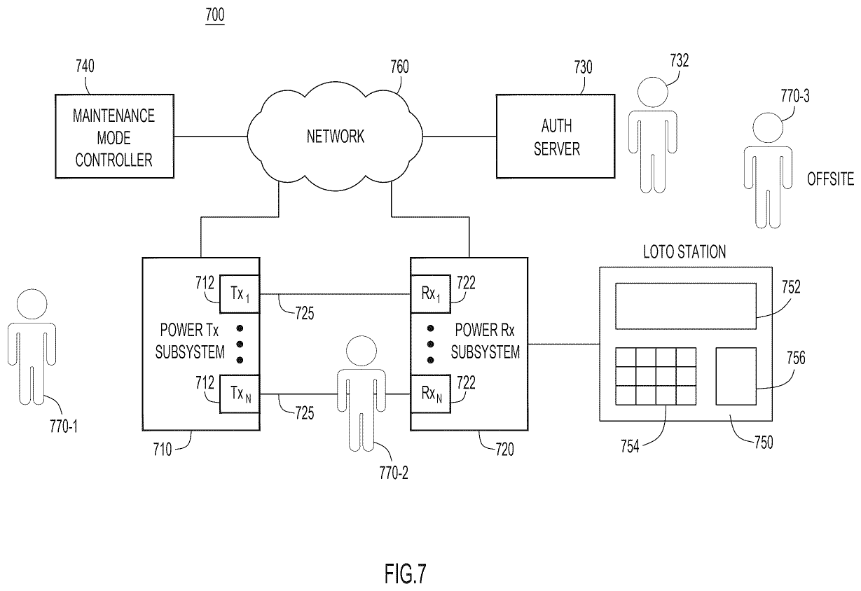

Turning now to FIGS. 7-10 for a description of further embodiments to support multi-user access to, and control of, the various maintenance modes and states described above. FIG. 7 shows a block diagram of a system 700 that includes a power Tx subsystem 710 having one or a plurality of power transmitters 712, a power Rx subsystem 720 having one or a plurality of power receivers 722, an auth service 730 and an associated administrator 732, a maintenance mode controller 740 and a lock-out tag-out (LOTO) station 750. There are one or more power/data cables 725 connected between the power Tx subsystem and power Rx subsystem. Each of these entities/equipment may have network connectivity so as to communicate with each other via network 760 in a cloud network arrangement. The functions of the power Tx subsystem 710, power Rx subsystem 720 and auth service 730 have been described above. There may be several users, shown 770-1, 770-2 and 770-3, at different locations within the system, and one or more of these users may be seeking to initiate a maintenance mode operation at the same time a maintenance mode has already been initiated by another user. The auth service 730 may run an tracking service that tracks the maintenance modes/states of the power Tx subsystem 710 and/or power Rx subsystem 720 across multiple users, e.g., users 770-1, 770-2 and 770-3. User 770-1 may be proximate the power Tx subsystem 710, user 770-2 may be interacting with a power cable 725 and user 770-3 may be offsite from the power Tx subsystem 710 and power Rx subsystem.

The LOTO station 750 may be a physical device deployed in the area of a power Tx subsystem or power Rx subsystem and physically connected to one or both equipment. For simplicity, FIG. 7 shows the LOTO station 750 connected to the power Rx subsystem 720. The LOTO station has a display screen 752 (that may or may not be touch-screen capable), a keypad or keyboard 754 and an optional badge/card reader 756. The LOTO station 750 can show on the display screen 752 how many people have the associated equipment (the power Rx subsystem 72) locked out. If the cloud-based state tracking performed by the auth service 730 goes down or loses communication with the power Tx subsystem 710 or power Rx subsystem 720, the LOTO station 750 can show the latest state of power Rx subsystem 720. The LOTO station 750 can be used to remove power control (from other users) until all other users have completed a lock-out tag-out.

There are multiple ways that a user may effect a lock-out:
Security badge access (via badge reader 756) on the LOTO station;
Account access via the keypad/keyboard 754 on the LOTO station;
Smartphone access via a maintenance application (as described above in connection with FIGS. 1A, 1B, 3, 4, 5A and 5B);
A dedicated (company-issued) device; and
Any authenticated device now known or hereinafter developed.

The lock-out tag-out process, described in more detail below, may be manually controlled by the administrator 732 at the control station/NOC, or software/computer-based based on software running at the auth service, the LOTO station 750, the power Tx subsystem 710, power Rx subsystem or on the maintenance application running on a user device. A “tag” may be a virtual data object the represents a particular user or user device for an associated user application (e.g., maintenance application running on a user device).

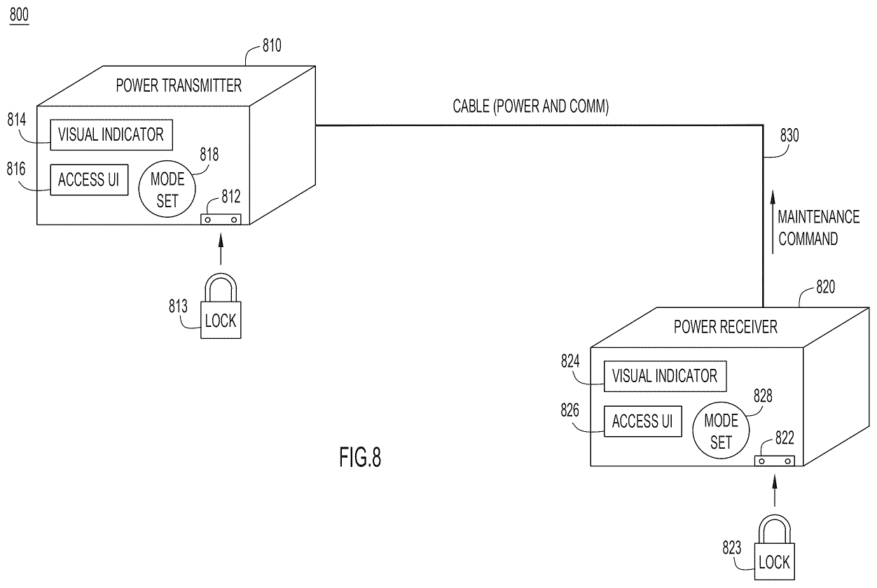

Turning now to FIG. 8, a diagram of a power delivery system 800 that depicts an arrangement for managing multi-user access to maintenance mode activity. The system 800 includes a power transmitter 810 and a power receiver 820, where each is shown as a dedicated “box” of equipment. The power transmitter 810 and the power receiver 820 are in communication with each other for power (and communications/data) via cable 830. The power transmitter 810 may include a lock receptacle 812 configured to receive and detect the placement of a physical lock (padlock) 813, a visual indicator 814 (e.g., a display screen or one or more LEDs) to display a state (e.g., maintenance mode) of the power transmitter, an access user interface (UI) device 816 and a mode set button 818. Similarly, the power receiver 820 may include a lock receptable 822 configured to receive and detect the placement of a physical lock (padlock) 823, a visual indicator 824 (e.g., a display screen or one or more LEDs) to display a state (e.g., maintenance mode) of the power, an access user interface (UI) device 826 and a mode set button 828.

The lock receptacle 812 is configured to detect presence of the physical lock 813 to enable the user to shut down power of the power transmitter or activate/enter any maintenance mode. A user may initiate a mode by activating the mode set button 818, which can result in selection of particular mode (by scrolling through various modes displayed on the visual indicator 814) or by a simple push of the mode set button to activate a mode (e.g., power shut down).

The access UI device 816 may be a badge/card reader, keyboard or other device to allow a user to enter credentials to gain access to the maintenance mode capabilities of the power transmitter 810.

Similarly, at the power receiver 820, the lock receptable 822 is configured to detect presence of the physical lock 823 to enable the user to initiate a maintenance mode. For example, the lock receptable 822 may detect the presence of the physical lock 823, then send a maintenance command, via cable 830 to the power transmitter 810 to power off or power down to a low voltage (e.g., 48 V) on that power channel, and when the physical lock 823 is removed, power at the power transmitter may resume to normal/previous power level. Likewise, a user at the power receiver 820 may gain access to the power receiver via the access UI device and initiate a maintenance mode via the mode set button 828.

To be complete, the various maintenance modes/states that could be entered include:
Power Off (power is terminated at the power transmitter);
Low voltage (e.g., 48 V) only (power is reduced to a low voltage at the power transmitter);
Low voltage with timer (power is reduced to a low voltage for a period of time);
Power is On with no fault check with timer (power goes back to low voltage when timer expires);
Fault managed power with timer (goes back to low voltage when timer expires);
Fault managed power with increased fault sensitivity;
Fault managed power with reduced fault sensitivity; and
Fault check command (user initiated fault check run in the system).

FIG. 9 illustrates a flow chart for a decision process 900 that may be used to account for multiple users that may contend for maintenance mode control in a power delivery system as described herein. The decision process 900 may be executed by the maintenance mode controller referred to in connection with FIGS. 1A, 3 and 4. The decision process 900 generally operates on the principle that the first user who puts the lock on controlled equipment choses the maintenance mode. More users can lock in for that state set by the first user. Each user that subsequently joins implicitly agrees with the current maintenance mode, or that user can wait until notified that the user can control the maintenance mode. One property of a given maintenance mode is a so-called “hazard level” which relates to the nature/extent of power interruption to be made on the equipment at issue or over a cable between equipment. The process 900 is designed to manage how maintenance modes transition in multi-user environments and these maintenance mode transitions have hazard level consequences.

The decision process 900 begins (and reverts to) a state in which no maintenance mode is set, as shown at step 905. A user request is received to change a maintenance mode (with an associated hazard level), at step 910. At step 915, the relevant equipment (power transmitter and/or power receiver) is locked at the requested maintenance mode. The lock-holding user may request to release the mode lock at step 920. When this occurs, then at step 925, the decision process 900 determines whether all user locks are now removed, as a result of the release at step 920, and the process reverts back to step 905. At this point, there are no remaining user locks and it is safe to change the maintenance mode for the equipment or return to normal operation. If at step 925, it is determined that all the user locks are not removed, then the process goes back to step 915 where the equipment continues to be locked at the requested maintenance mode.

At step 930, a new user requests to set the maintenance mode. When this occurs, then at step 935, the decision process 900 determines whether the newly requested maintenance mode matches the current maintenance mode. If the determination is positive at step 935, then the new user's lock is added to the current maintenance mode at step 940. If the determination is negative at step 935 (the newly requested maintenance mode does not match the current maintenance mode), then at step 945, a determination is made as to whether the new request is authorized to override the current/active maintenance mode. If it is determined in step 940 that the new request is authorized to override the current/active maintenance mode, then at step 945, a notification is made to the other one or more users that hold a lock on the maintenance to notify such other one or more users of the newly requested override maintenance mode, and thereafter the decision process goes to step 915 to lock the equipment at the newly requested maintenance mode (the one that was determined to be authorized to override the current maintenance mode). If at step 940 it is determined that the new request is not authorized to override the current/active maintenance mode, then at step 950, that request is added to a queue until all maintenance mode locks are released, or some other wait policy is executed.

The system and methods presented herein provide for a multi-channel (multi-transmitter multi-receiver) arrangement and with a digital lock-out/tag-out station, either on an application or on a physical station, with multiple methods of authentication. On the backend, a communication is made with the power transmitter to turn it off, and when safe, turn it back on.

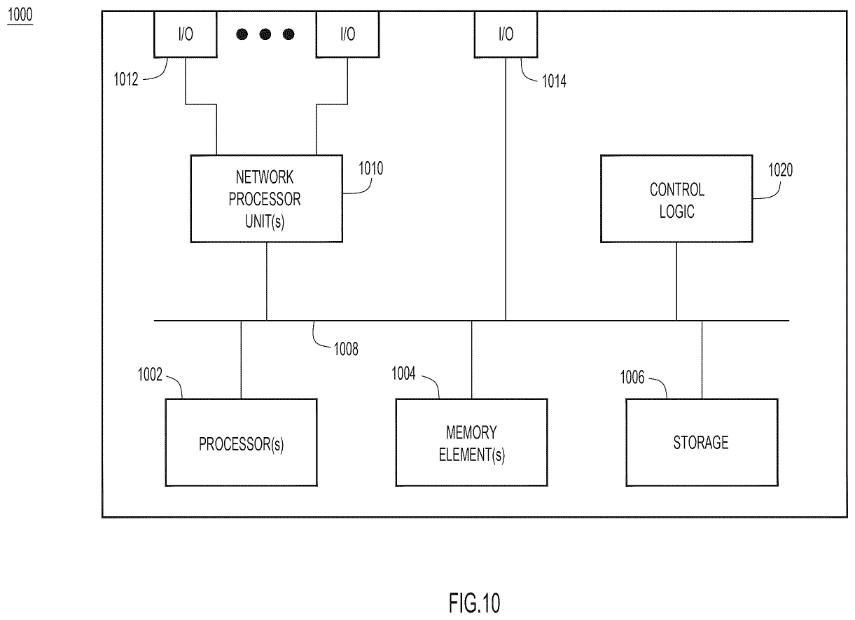

Referring to FIG. 10, FIG. 10 illustrates a hardware block diagram of a computing device 1000 that may perform functions associated with operations discussed herein in connection with the techniques depicted in FIGS. 1A, 1B, 2-4, 5A, 5B and 6-9. In various embodiments, a computing device or apparatus, such as computing device 1000 or any combination of computing devices 1000, may be configured as any entity/entities as discussed for the techniques presented herein.

In at least one embodiment, the computing device 1000 may be any apparatus that may include one or more processor(s) 1002, one or more memory element(s) 1004, storage 1006, a bus 1008, one or more network processor unit(s) 1010 interconnected with one or more network input/output (I/O) interface(s) 1012, one or more I/O interface(s) 1014, and control logic 1020. In various embodiments, instructions associated with logic for computing device 1000 can overlap in any manner and are not limited to the specific allocation of instructions and/or operations described herein.

In at least one embodiment, processor(s) 1002 is/are at least one hardware processor configured to execute various tasks, operations and/or functions for computing device 1000 as described herein according to software and/or instructions configured for computing device 1000. Processor(s) 1002 (e.g., a hardware processor) can execute any type of instructions associated with data to achieve the operations detailed herein. In one example, processor(s) 1002 can transform an element or an article (e.g., data, information) from one state or thing to another state or thing. Any of potential processing elements, microprocessors, digital signal processor, baseband signal processor, modem, PHY, controllers, systems, managers, logic, and/or machines described herein can be construed as being encompassed within the broad term ‘processor’.

In at least one embodiment, memory element(s) 1004 and/or storage 1006 is/are configured to store data, information, software, and/or instructions associated with computing device 1000, and/or logic configured for memory element(s) 1004 and/or storage 1006. For example, any logic described herein (e.g., control logic 1020) can, in various embodiments, be stored for computing device 1000 using any combination of memory element(s) 1004 and/or storage 1006. Note that in some embodiments, storage 1006 can be consolidated with memory element(s) 1004 (or vice versa), or can overlap/exist in any other suitable manner.

In at least one embodiment, bus 1008 can be configured as an interface that enables one or more elements of computing device 1000 to communicate in order to exchange information and/or data. Bus 1008 can be implemented with any architecture designed for passing control, data and/or information between processors, memory elements/storage, peripheral devices, and/or any other hardware and/or software components that may be configured for computing device 1000. In at least one embodiment, bus 1008 may be implemented as a fast kernel-hosted interconnect, potentially using shared memory between processes (e.g., logic), which can enable efficient communication paths between the processes.

In various embodiments, network processor unit(s) 1010 may enable communication between computing device 1000 and other systems, entities, etc., via network I/O interface(s) 1012 (wired and/or wireless) to facilitate operations discussed for various embodiments described herein. In various embodiments, network processor unit(s) 1010 can be configured as a combination of hardware and/or software, such as one or more Ethernet driver(s) and/or controller(s) or interface cards, Fibre Channel (e.g., optical) driver(s) and/or controller(s), wireless receivers/transmitters/transceivers, baseband processor(s)/modem(s), and/or other similar network interface driver(s) and/or controller(s) now known or hereafter developed to enable communications between computing device 1000 and other systems, entities, etc. to facilitate operations for various embodiments described herein. In various embodiments, network I/O interface(s) 1012 can be configured as one or more Ethernet port(s), Fibre Channel ports, any other I/O port(s), and/or antenna(s)/antenna array(s) now known or hereafter developed. Thus, the network processor unit(s) 1010 and/or network I/O interface(s) 1012 may include suitable interfaces for receiving, transmitting, and/or otherwise communicating data and/or information in a network environment.

I/O interface(s) 1014 allow for input and output of data and/or information with other entities that may be connected to computing device 1000. For example, I/O interface(s) 1014 may provide a connection to external devices such as a keyboard, keypad, a touch screen, and/or any other suitable input and/or output device now known or hereafter developed. In some instances, external devices can also include portable computer readable (non-transitory) storage media such as database systems, thumb drives, portable optical or magnetic disks, and memory cards. In still some instances, external devices can be a mechanism to display data to a user, such as, for example, a computer monitor, a display screen, or the like.

In various embodiments, control logic 1020 can include instructions that, when executed, cause processor(s) 1002 to perform operations, which can include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1020) may be identified based upon application(s) for which they are implemented in a specific embodiment. However, it should be appreciated that any particular program nomenclature herein is used merely for convenience; thus, embodiments herein should not be limited to use(s) solely described in any specific application(s) identified and/or implied by such nomenclature.

In various embodiments, any entity or apparatus as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, memory element(s) 1004 and/or storage 1006 can store data, software, code, instructions (e.g., processor instructions), logic, parameters, combinations thereof, and/or the like used for operations described herein. This includes memory element(s) 1004 and/or storage 1006 being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

In some aspects, the techniques described herein relate to a system including: a power transmitter subsystem configured to transmit power over one or more cables; a power receiver subsystem configured to receive the power over the one or more cables; a user interface configured to initiate a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and an authorization server configured to authorize initiation of the maintenance mode on the power transmitter subsystem and power receiver subsystem.

In some aspects, the techniques described herein relate to a system, wherein the user interface includes a button on a component of the power transmitter subsystem or a component of the power receiver subsystem.

In some aspects, the techniques described herein relate to a system, wherein the user interface is part of a device that is separate from the power transmitter subsystem or the power receiver subsystem.

In some aspects, the techniques described herein relate to a system, wherein the authorization server is provisioned with an authorization key pair, and the power transmitter subsystem and power receiver subsystem are configured to store authorization certificates.

In some aspects, the techniques described herein relate to a system, further including a maintenance mode controller that is part of or separate from the power transmitter subsystem or power receiver subsystem and is configured to resolve conflicts between multiple maintenance mode requests made on the power transmitter subsystem or power receiver subsystem.

In some aspects, the techniques described herein relate to a system, wherein the user interface is part of a portable user device, and wherein: the user device is configured to send to the authorization server a request to initiate the maintenance mode; the authorization server is configured to evaluate the request for approval, and if the request is approved, send to the maintenance mode controller an authorized request to initiate the maintenance mode; and the maintenance mode controller is configured to send to the power transmitter subsystem or the power receiver subsystem a notification of indicating the maintenance mode to be initiated by which power is interrupted according to the maintenance mode.

In some aspects, the techniques described herein relate to a system, wherein the maintenance mode causes the power transmitter subsystem to provide relatively low voltage power to the power receiver subsystem that is safe to touch by a human.

In some aspects, the techniques described herein relate to a system, wherein the maintenance mode causes the power transmitter subsystem to provide power to the power receiver subsystem without any fault detection being performed by the power transmitter subsystem and the power receiver subsystem for a period of time, and at expiration of the period of time, the power transmitter subsystem stops providing power to the power receiver subsystem.

In some aspects, the techniques described herein relate to a system, wherein the power transmitter subsystem and power receiver subsystem are responsive to a request to disable the maintenance mode and return to a state when the maintenance mode was initiated.

In some aspects, the techniques described herein relate to a system, wherein the power transmitter subsystem and power receiver subsystem are responsive to a request to perform a complete restart and reset all states when the maintenance mode is completed.

In some aspects, the techniques described herein relate to a system, wherein the maintenance mode causes the power transmitter subsystem to stop providing the power to the power receiver subsystem without any time limit, and the authorization server is configured to respond to a request to turn the power transmitter subsystem back on to provide the power to the power receiver subsystem.

In some aspects, the techniques described herein relate to a system, wherein the maintenance mode causes the power transmitter subsystem to stop providing the power to the power receiver subsystem for a period of time, and at expiration of the period of time, the power transmitter subsystem is restarted.

In some aspects, the techniques described herein relate to a system, further including a plurality of power receiver subsystems each of which separately receives power from the power transmitter subsystem.

In some aspects, the techniques described herein relate to a system, further including a maintenance mode controller configured to control maintenance mode initiation among a plurality of users such that a particular maintenance mode of a plurality of maintenance modes, is locked for a first user among the plurality of users according to time of initiation of the particular maintenance mode.

In some aspects, the techniques described herein relate to a system, wherein the maintenance mode controller is configured to release lock of the particular maintenance mode when the first user has requested release of lock of the particular maintenance mode and one or more additional users have requested release of lock of the particular maintenance mode, and thereafter to initiate a different maintenance mode in response to a request from one of the plurality of users.

In some aspects, the techniques described herein relate to a system, wherein the maintenance mode controller is further configured to receive a from a second user a request to set a maintenance mode, determine whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

In some aspects, the techniques described herein relate to a system, wherein the maintenance mode controller is further configured to determine whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.

In some aspects, the techniques described herein relate to a system, wherein the maintenance mode controller is one of: a stand-alone controller entity, integrated into the power transmitter subsystem, integrated into the power receiver subsystem, or integrated into the authorization server.

In some aspects, the techniques described herein relate to a method including: providing power from a power transmitter subsystem to a power receiver subsystem over one or more cables; initiating a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and authorizing initiation of the maintenance mode on the power transmitter subsystem and power receiver subsystem.

In some aspects, the techniques described herein relate to a method, wherein initiating includes receiving an input via a button on a component of the power transmitter subsystem or the power receiver subsystem.

In some aspects, the techniques described herein relate to a method, wherein initiating includes receiving an input from a device that is separate from the power transmitter subsystem or the power receiver subsystem.

In some aspects, the techniques described herein relate to a method, further including: controlling maintenance mode initiation among a plurality of users such that a particular maintenance mode of a plurality of maintenance modes, is locked for a first user among the plurality of users according to time of initiation of the particular maintenance mode.

In some aspects, the techniques described herein relate to a method, wherein controlling includes releasing lock of the particular maintenance mode when the first user has requested release of lock of the particular maintenance mode and one or more additional users have requested release of lock of the particular maintenance mode, and thereafter initiating a different maintenance mode in response to a request from one of the plurality of users.

In some aspects, the techniques described herein relate to a method, wherein controlling includes receiving a from a second user a request to set a maintenance mode, determining whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

In some aspects, the techniques described herein relate to a method, wherein controlling further includes determining whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.

In some aspects, the techniques described herein relate to an apparatus including: a network interface configured to enable network communications, including communications with a power transmitter subsystem that transmits power over one or more cables, and a power receiver subsystem that receives the power over the one or more cables; and one or more computer processors coupled to the network interface, the one or more computer processors configured to: receive a request to initiate a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and authorize initiation of the maintenance mode on the power transmitter subsystem and power receiver subsystem.

In some aspects, the techniques described herein relate to an apparatus, wherein the one or more computer processors are configured to control maintenance mode initiation among a plurality of users such that a particular maintenance mode of a plurality of maintenance modes, is locked for a first user among the plurality of users according to time of initiation of the particular maintenance mode.

In some aspects, the techniques described herein relate to an apparatus, wherein the one or more computer processors are configured to release lock of the particular maintenance mode when the first user has requested release of lock of the particular maintenance mode and one or more additional users have requested release of lock of the particular maintenance mode, and thereafter to initiate a different maintenance mode in response to a request from one of the plurality of users.

In some aspects, the techniques described herein relate to an apparatus, wherein the one or more computer processors are configured to receive a from a second user a request to set a maintenance mode, determine whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

In some aspects, the techniques described herein relate to an apparatus, wherein the one or more computer processors are configured to determine whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A system comprising:
a power transmitter subsystem configured to transmit power over one or more cables;
a power receiver subsystem configured to receive the power over the one or more cables;
a user interface configured to initiate a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and
an authorization server configured to authorize initiation of the maintenance mode on the power transmitter subsystem and power receiver subsystem.

2. The system of claim 1, wherein the user interface includes a button on a component of the power transmitter subsystem or a component of the power receiver subsystem.

3. The system of claim 1, wherein the user interface is part of a device that is separate from the power transmitter subsystem or the power receiver subsystem.

4. The system of claim 3, wherein the authorization server is provisioned with an authorization key pair, and the power transmitter subsystem and power receiver subsystem are configured to store authorization certificates.

5. The system of claim 1, further comprising a maintenance mode controller that is part of or separate from the power transmitter subsystem or power receiver subsystem and is configured to resolve conflicts between multiple maintenance mode requests made on the power transmitter subsystem or power receiver subsystem.

6. The system of claim 5, wherein the user interface is part of a user device, and wherein:
the user device is configured to send to the authorization server a request to initiate the maintenance mode;
the authorization server is configured to evaluate the request for approval, and if the request is approved, send to the maintenance mode controller an authorized request to initiate the maintenance mode; and
the maintenance mode controller is configured to send to the power transmitter subsystem or the power receiver subsystem a notification of indicating the maintenance mode to be initiated by which power is interrupted according to the maintenance mode.

7. The system of claim 1, wherein the maintenance mode causes the power transmitter subsystem to provide relatively low voltage power to the power receiver subsystem that is safe to touch by a human.

8. The system of claim 1, wherein the maintenance mode causes the power transmitter subsystem to provide power to the power receiver subsystem without any fault detection being performed by the power transmitter subsystem and the power receiver subsystem for a period of time, and at expiration of the period of time, the power transmitter subsystem stops providing power to the power receiver subsystem.

9. The system of claim 1, wherein the power transmitter subsystem and power receiver subsystem are responsive to a request to disable the maintenance mode and return to a state when the maintenance mode was initiated.

10. The system of claim 1, wherein the power transmitter subsystem and power receiver subsystem are responsive to a request to perform a complete restart and reset all states when the maintenance mode is completed.

11. The system of claim 1, wherein the maintenance mode causes the power transmitter subsystem to stop providing the power to the power receiver subsystem without any time limit, and the authorization server is configured to respond to a request to turn the power transmitter subsystem back on to provide the power to the power receiver subsystem.

12. The system of claim 1, wherein the maintenance mode causes the power transmitter subsystem to stop providing the power to the power receiver subsystem for a period of time, and at expiration of the period of time, the power transmitter subsystem is restarted.

13. The system of claim 1, further comprising a plurality of power receiver subsystems each of which separately receives power from the power transmitter subsystem.

14. The system of claim 1, further comprising a maintenance mode controller configured to control maintenance mode initiation among a plurality of users such that a particular maintenance mode of a plurality of maintenance modes, is locked for a first user among the plurality of users according to time of initiation of the particular maintenance mode.

15. The system of claim 14, wherein the maintenance mode controller is configured to release lock of the particular maintenance mode when the first user has requested release of lock of the particular maintenance mode and one or more additional users have requested release of lock of the particular maintenance mode, and thereafter to initiate a different maintenance mode in response to a request from one of the plurality of users.

16. The system of claim 14, wherein the maintenance mode controller is further configured to receive a from a second user a request to set a maintenance mode, determine whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

17. The system of claim 16, wherein the maintenance mode controller is further configured to determine whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.

18. The system of claim 14, wherein the maintenance mode controller is one of: a stand-alone controller entity, integrated into the power transmitter subsystem, integrated into the power receiver subsystem, or integrated into the authorization server.

19. A method comprising:
providing power from a power transmitter subsystem to a power receiver subsystem over one or more cables;
initiating a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and
authorizing initiation of the maintenance mode on the power transmitter subsystem and power receiver subsystem.

20. The method of claim 19, wherein initiating includes receiving an input via a button on a component of the power transmitter subsystem or the power receiver subsystem.

21. The method of claim 19, wherein initiating includes receiving an input from a device that is separate from the power transmitter subsystem or the power receiver subsystem.

22. The method of claim 19, further comprising:
controlling maintenance mode initiation among a plurality of users such that a particular maintenance mode of a plurality of maintenance modes, is locked for a first user among the plurality of users according to time of initiation of the particular maintenance mode.

23. The method of claim 22, wherein controlling includes releasing lock of the particular maintenance mode when the first user has requested release of lock of the particular maintenance mode and one or more additional users have requested release of lock of the particular maintenance mode, and thereafter initiating a different maintenance mode in response to a request from one of the plurality of users.

24. The method of claim 23, wherein controlling includes receiving a from a second user a request to set a maintenance mode, determining whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

25. The method of claim 24, wherein controlling further includes determining whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.

26. An apparatus comprising:
a network interface configured to enable network communications, including communications with a power transmitter subsystem that transmits power over one or more cables, and a power receiver subsystem that receives the power over the one or more cables; and
one or more computer processors coupled to the network interface, the one or more computer processors configured to:
receive a request to initiate a maintenance mode associated with the power transmitter subsystem and the power receiver subsystem, the maintenance mode causing the power transmitter subsystem and power receiver subsystem to enter a power mode to allow for maintenance activity to be performed at the power transmitter subsystem and power receiver subsystem; and
authorize initiation of the maintenance mode on the power transmitter subsystem and power receiver subsystem.

27. The apparatus of claim 26, wherein the one or more computer processors are configured to control maintenance mode initiation among a plurality of users such that a particular maintenance mode of a plurality of maintenance modes, is locked for a first user among the plurality of users according to time of initiation of the particular maintenance mode.

28. The apparatus of claim 27, wherein the one or more computer processors are configured to release lock of the particular maintenance mode when the first user has requested release of lock of the particular maintenance mode and one or more additional users have requested release of lock of the particular maintenance mode, and thereafter to initiate a different maintenance mode in response to a request from one of the plurality of users.

29. The apparatus of claim 27, wherein the one or more computer processors are configured to receive a from a second user a request to set a maintenance mode, determine whether the request from the second user is for a maintenance mode that matches a currently active maintenance mode, and when it is determined that the request from the second user is for a maintenance mode that matches the currently active maintenance mode, then adding a lock for the second user at the currently active maintenance mode.

30. The apparatus of claim 29, wherein the one or more computer processors are configured to determine whether the request from the second user is authorized to override the currently active maintenance mode, and when it is determined that the second user is authorized to override the currently active maintenance mode, then notifying one or more other lock holders of an override and setting the maintenance mode requested by the second user as the currently active maintenance mode, and when it is determined that the second user is not authorized to override the currently active maintenance mode, then adding the request from the second user to a queue until all other maintenance mode locks are released.
